(19) United States
(12) Patent Application Publication
(10) Pub. No.: US 2019/0071771 A1
(43) Pub. Date: Mar. 7, 2019

(54) SEMICONDUCTOR MANUFACTURING APPARATUS AND MANUFACTURING METHOD OF SEMICONDUCTOR DEVICE

(71) Applicant: TOSHIBA MEMORY CORPORATION, Minato-ku (JP)

(72) Inventors: Fumiki AISO, Kuwana (JP); Kensei TAKAHASHI, Kuwana (JP); Tomohisa IINO, Yokkaichi (JP)

(73) Assignee: TOSHIBA MEMORY CORPORATION, Minato-ku (JP)

(21) Appl. No.: 15/919,268

(22) Filed: Mar. 13, 2018

(30) Foreign Application Priority Data
Sep. 7, 2017 (JP) 2017-172362

(51) Int. Cl. C23C 16/44; H01L 21/02; C23C 16/34; C23C 16/455; C23C 16/56

(52) U.S. Cl. CPC C23C 16/4408; H01L 21/0228; C23C 16/56; C23C 16/4405; C23C 16/45527; C23C 16/34

(57) ABSTRACT

According to an embodiment, a semiconductor manufacturing apparatus includes a chamber, a process gas nozzle, an inert gas nozzle and a hydrogen radical nozzle. The chamber houses at least one substrate. The process gas nozzle is to release process gas toward the substrate in the chamber. The inert gas nozzle is to release inert gas toward the substrate in the chamber. The hydrogen radical nozzle is disposed in the chamber and is to generate hydrogen radicals by heating raw material gas including hydrogen and to release the generated hydrogen radicals toward the substrate during the release of the inert gas. A metal wire is in the hydrogen radical nozzle, and the metal wire includes a metal catalyst for exciting the generation of the hydrogen radicals.

### CROSS-REFERENCE TO RELATED APPLICATIONS

This application is based upon and claims the benefit of priority from Japanese Patent Application No. 2017-172362, filed on Sep. 7, 2017; the entire contents of which are incorporated herein by reference.

### FIELD

Embodiments of the present invention relate to a semiconductor manufacturing apparatus and a manufacturing method of a semiconductor device.

### BACKGROUND

When a film is formed on a substrate in an atomic layer deposition (ALD) method, there is sometimes a case of using process gas that includes a halogen element. This halogen element is not necessary after the film formation. Therefore, for example, inert gas is used as material for removing the halogen element sticking onto the substrate.

Nevertheless, the activation energy of a halogen element is large. Hence, it takes much time to remove the halogen element solely with the inert gas. This accordingly makes shortening a time for a film formation process difficult.

According to embodiments of the present invention, there are provided a semiconductor manufacturing apparatus and a manufacturing method of a semiconductor device capable of shortening a time for a film formation process in an ALD method.

### BRIEF DESCRIPTION OF THE DRAWINGS

FIG. 1 is a schematic plan view of a semiconductor manufacturing apparatus according to a first embodiment;

FIG. 2 is a diagram schematically showing the essential part of the semiconductor manufacturing apparatus according to the first embodiment;

FIG. 3 is a flowchart of steps for film formation on a substrate;

FIG. 4 is a schematic plan view of a semiconductor manufacturing apparatus according to a second embodiment; and

FIG. 5 is a diagram schematically showing the essential part of the semiconductor manufacturing apparatus according to the second embodiment.

### DETAILED DESCRIPTION

Embodiments will now be explained with reference to the accompanying drawings. The present invention is not limited to the embodiments.

### First Embodiment

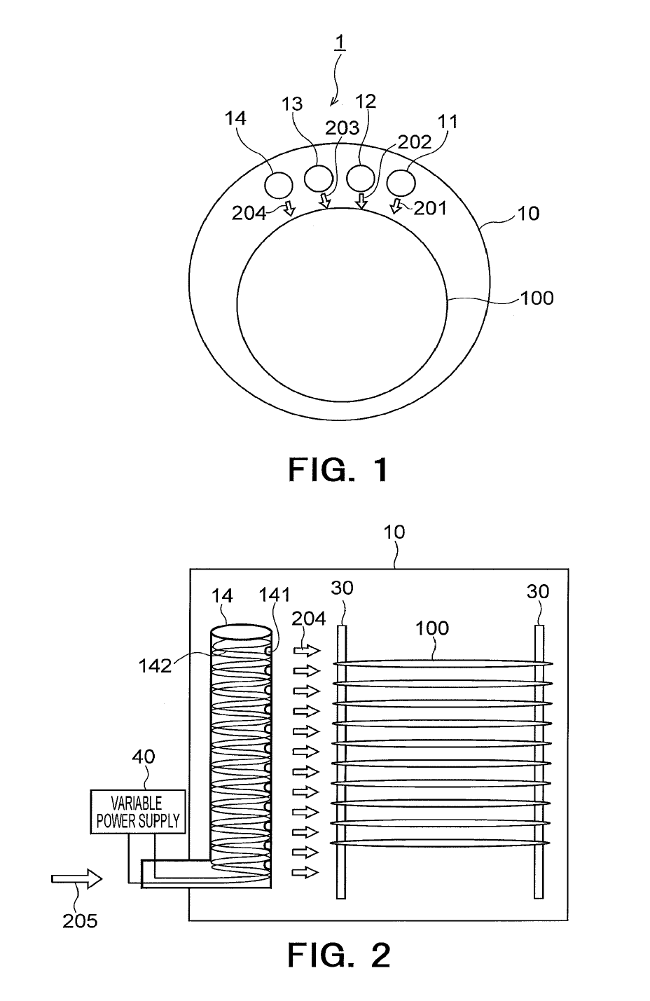

FIG. 1 is a schematic plan view of a semiconductor manufacturing apparatus according to a first embodiment. Moreover, FIG. 2 is a diagram schematically showing the essential part of the semiconductor manufacturing apparatus according to the first embodiment. A semiconductor manufacturing apparatus 1 according to the present embodiment is a batch ALD apparatus which collectively forms films on a plurality of substrates 100 in an ALD method. Specifically, the semiconductor manufacturing apparatus 1 includes a chamber 10, nozzles 11 to 14, support members 30 and a variable power supply 40.

The chamber 10 houses the nozzles 11 to 14 and the support members 30. The interior of the chamber 10 can be evacuated into a vacuum state. In the chamber 10, the support members 30 which are columnar support the plurality of substrates 100 with these substrates 100 stacked on one another. The support members 30 can rotate with the substrates 100 supported thereon.

The nozzle 11 releases precursor gas 201. The nozzle 12 releases reactant gas 202. The nozzle 11 corresponds to a first process gas nozzle. The nozzle 12 corresponds to a second process gas nozzle. Moreover, the precursor gas 201 and the reactant gas 202 correspond to process gas for forming films on the wafer-like substrates 100. For example, when a film of aluminum oxide (Al₂O₃) is formed on the substrate 100, the precursor gas 201 includes aluminum chloride (AlCl₃), and the reactant gas 202 includes ozone (O₃). Moreover, when a film of titanium nitride (TiN) is formed on the substrate 100, the precursor gas 201 includes titanium tetrachloride (TiCl₄), and the reactant gas 202 includes ammonia (NH₃).

The nozzle 13 corresponds to an inert gas nozzle that releases inert gas 203. For the inert gas 203, for example, nitrogen (N₂) gas, argon (Ar) gas, xenon (Xe) gas or the like is used.

The nozzle 14 corresponds to a hydrogen radical nozzle that releases hydrogen radicals 204. Referring to FIG. 2, a structure of the nozzle 14 is herein described. As shown in FIG. 2, raw material gas 205 which is a raw material of the hydrogen radicals 204 is fed to the nozzle 14. For the raw material gas 205, for example, hydrogen gas, ammonia gas or the like is used.

Moreover, the nozzle 14 has a plurality of release ports 141 for releasing the hydrogen radicals 204. The plurality of release ports 141 are provided along a stack direction of the substrates 100, in other words, along the vertical direction. The release ports 141 individually correspond to the substrates 100. Each release port 141 is preferably positioned so as to release the hydrogen radicals 204 toward the surface of the substrate 100. Notably, release ports similar to the release ports 141 are also provided in the other nozzles.

A metal wire 142 is provided in the nozzle 14. The metal wire 142 is connected to the variable power supply 40. Upon supply of a current from the variable power supply 40 to the metal wire 142, the metal wire 142 generates heat. Thereby, the raw material gas 205 is heated. As a result, the hydrogen radicals 204 are generated. In this stage, since the metal wire 142 includes a metal catalyst for exciting the generation of the hydrogen radicals 204, for example, tungsten, the generation of the hydrogen radicals 204 is promoted.

The shape of the metal wire 142 in the nozzle 14 is sufficient to be any shape in which the hydrogen radicals 204 can be generated at least near the release ports 141. Therefore, the shape of the metal wire 142 may be helical as in the present embodiment, or may be any other shape, for example, a linear shape.

Hereafter, a manufacturing method of a semiconductor device using the aforementioned semiconductor manufacturing apparatus 1 is described. A film formation process for the substrates 100 is herein described. Notably, in this film formation process, the support members 30 are rotating inward of the nozzles 11 to 14.

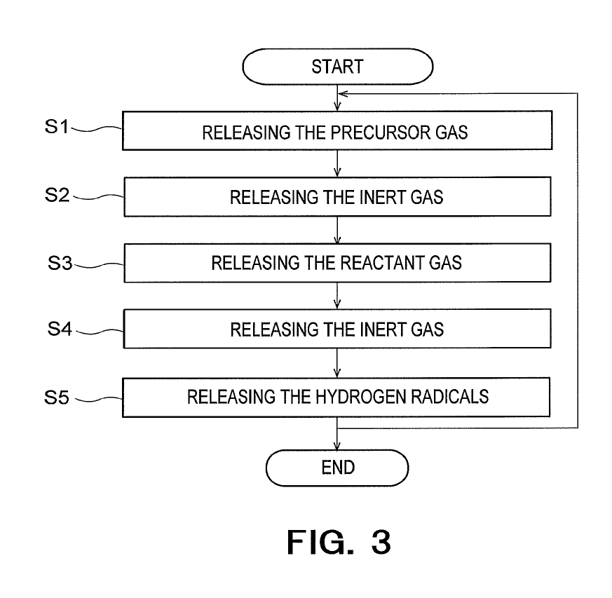

FIG. 3 is a flowchart of steps for film formation on the substrates 100. First, the precursor gas 201 including halogen elements (for example, chlorine) is released from the nozzle 11 toward each substrate 100 (step S1). As a result, a part of the precursor gas 201 is deposited on the surface of each substrate 100.

Subsequently, the inert gas 203 is released from the nozzle 13 toward each substrate 100 (step S2). Thereby, the precursor gas 201 that is floating in the chamber 10 is purged.

Next, the reactant gas 202 is released from the nozzle 12 toward each substrate 100 (step S3). Thereby, a chemical reaction between the precursor gas 201 and the reactant gas 202 occurs to deposit a compound on the surface of each substrate 100.

Next, the inert gas 203 is released from the nozzle 13 again (step S4). Thereby, the precursor gas 201 and the reactant gas 202 that are floating in the chamber 10 are purged.

Along with the aforementioned step S4, the variable power supply 40 supplies a current to the metal wire 142. The current supply allows the metal wire 142 to generate heat, and the generated heat heats the raw material gas 205. As a result, the hydrogen radicals 204 are generated in the nozzle 14. In this stage, the generation of the hydrogen radicals 204 is promoted by the metal catalyst contained in the metal wire 142. After that, the generated hydrogen radicals 204 are released from each release port 141 toward each substrate 100 (step S5).

The released hydrogen radicals 204 assist removal of halogen elements (chlorine in the present embodiment) sticking onto the surface of the substrate 100. The removed halogen elements are purged by the inert gas 203 along with other elements contained in the precursor gas 201 or the reactant gas 202.

In step S5, the generation of the hydrogen radicals 204 is affected by a temperature of heating the raw material gas 205. This heating temperature is associated with the current supplied to the metal wire 142. Accordingly, by adjusting the current by the variable power supply 40, the generation of the hydrogen radicals 204 can be optimized.

After the hydrogen radicals 204 are released as above, the aforementioned operation of steps S1 to S5 is repeated a preset number of times. As a result, a film having a predetermined thickness is formed on the surface of each substrate 100.

According to the present embodiment described above, the hydrogen radicals 204 are generated by heating the metal wire 142 provided in the nozzle 14, and the generated hydrogen radicals 204 are released toward the substrates 100. Since these hydrogen radicals 204 assist removal of halogen elements sticking onto the surfaces of the substrates 100, a time for releasing the inert gas 203 can be more shortened than before. As a result, a time for a film formation process can be shortened.

Moreover, in the present embodiment, the nozzle 14 is provided in the chamber 10. Hence, the distance from the nozzle 14 to the substrates 100 is short. Since the hydrogen radicals 204 generated in the nozzle 14 are therefore immediately released toward the substrates 100, halogen elements can be removed more quickly than before.

Moreover, in the present embodiment, the plurality of release ports 141 are provided in the nozzle 14 individually to the plurality of substrates 100. Therefore, the hydrogen radicals 204 can be locally released. As a result, the hydrogen radicals 204 can be effectively used for removing halogen elements.

### Second Embodiment

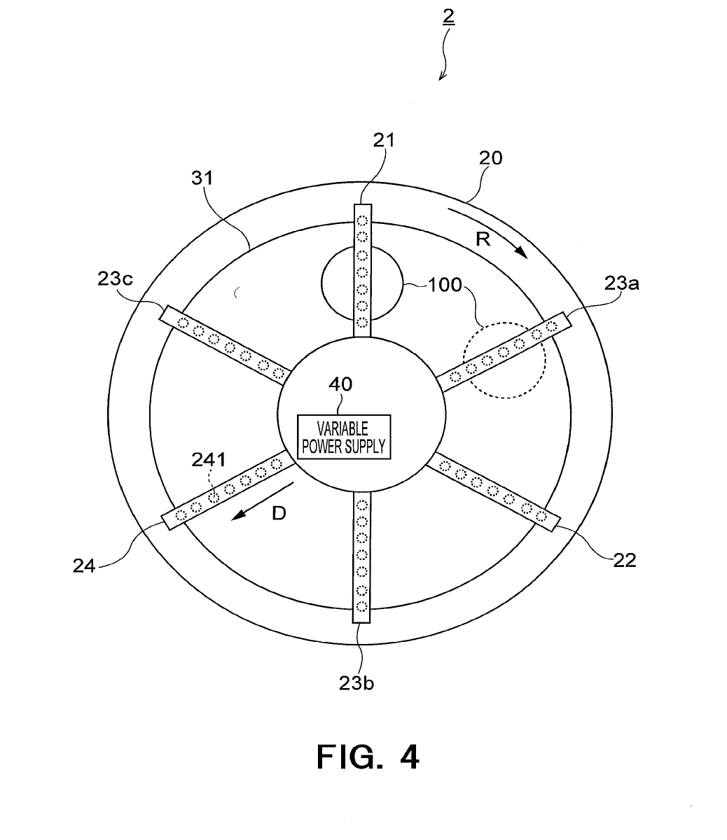

FIG. 4 is a schematic plan view of a semiconductor manufacturing apparatus according to a second embodiment. A semiconductor manufacturing apparatus 2 according to the present embodiment is a single-wafer ALD apparatus which forms a film on one substrate in an ALD method. Specifically, the semiconductor manufacturing apparatus 2 includes a chamber 20, nozzles 21 to 24, a support member 31 and a variable power supply 40.

The chamber 20 includes the nozzles and the support member 30. The interior of the chamber 20 can be evacuated into a vacuum state. The support member 31 which is circular support a substrate 100 in the chamber 20. Upon rotation of the support member 31, the substrate 100 is rotationally moved along a rotational direction R.

The nozzles are disposed above the support member 31 spaced from one another along the rotational direction R. In other words, the nozzles radially extend from the center of the rotation of the support member 31.

The nozzle 21 and the nozzle 22 respectively correspond to the nozzle 11 and the nozzle 12 described for the first embodiment. Namely, the nozzle 21 release the precursor gas 201, and the nozzle 22 releases the reactant gas 202.

The nozzle 23a is disposed between the nozzle 21 and the nozzle 22. The nozzle 23b is disposed between the nozzle 22 and the nozzle 24. The nozzle 23c is disposed between the nozzle 24 and the nozzle 21. The nozzles 23a to 23c correspond to the nozzle 13 described for the first embodiment. Namely, the nozzles 23a to 23c release the inert gas 203. In the present embodiment, the nozzles 23a to 23c release the inert gas 203 continuously. Therefore, in addition to a function to serve purge gas, the nozzles 23a to 23c also have a function to partition process regions with the precursor gas 201, the reactant gas 202 and the hydrogen radicals 204 from one another.

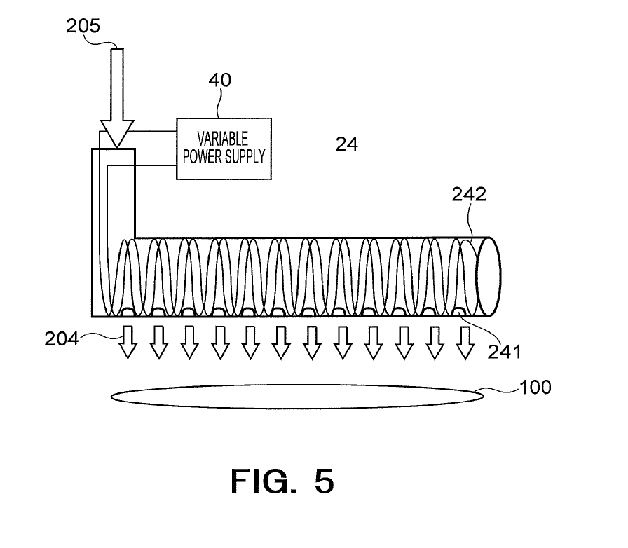

The nozzle 24 corresponds to the nozzle 14 described for the first embodiment. Referring to FIG. 5, a structure of the nozzle 24 is herein described. As shown in FIG. 5, the raw material gas 205 which includes hydrogen is fed to the nozzle 24. Moreover, the nozzle 24 releases the hydrogen radicals 204 from a plurality of release ports 241.

The plurality of release ports 241 are provided along a radial direction D from the center of rotation of the support member 31 (see FIG. 4). Each release port 241 releases the hydrogen radicals 204 toward the surface of the substrate 100. Notably, release ports similar to the release ports 241 are also provided in the other nozzles.

Furthermore, the metal wire 242 is provided in the nozzle 24. The metal wire 242 is connected to the variable power supply 40 similarly to the metal wire 142 described for the first embodiment. Moreover, it includes a metal catalyst for exciting generation of the hydrogen radicals 204, for example, tungsten.

Hereafter, a manufacturing method of a semiconductor device using the aforementioned semiconductor manufacturing apparatus 2 is described. A film formation process of the substrate 100 is herein described. A flow of this film formation process is similar to the flow of the film formation process described for the first embodiment. It should be noted that in the present embodiment, the precursor gas 201, the reactant gas 202, the inert gas 203 and the hydrogen radicals 204 are released continuously from the corresponding nozzles.

First, the precursor gas 201 is released from the nozzle 21 toward the substrate 100 when the substrate 100 faces the nozzle 21. After the elapse of a predetermined period, the support member 31 rotates in the rotational direction R. Thereby, the substrate 100 is moved to a position of facing the nozzle 23a. At this position, the inert gas 203 is released from the nozzle 23a toward the substrate 100 (step S2).

After that, the support member 31 rotates in the rotational direction R. Thereby, the substrate 100 is moved to a position of facing the nozzle 22. At this position, the reactant gas 202 is released from the nozzle 22 toward the substrate 100 (step S3).

After that, the support member 31 rotates in the rotational direction R. Thereby, the substrate 100 is moved to a position of facing the nozzle 23b. At this position, the inert gas 203 is released from the nozzle 23b toward the substrate 100 (step S4).

After that, the support member 31 rotates in the rotational direction R. Thereby, the substrate 100 is moved to a position of facing the nozzle 24. At this position, the hydrogen radicals 204 are released from the nozzle 24 toward the substrate 100 (step S5). Subsequently, the substrate 100 is returned again to the position of facing the nozzle 21 by rotation of the support member 31. After that, the rotation of the support member 31 is repeated a preset number of times, and thereby, a film having a predetermined thickness is formed on the surface of the substrate 100.

According to the present embodiment described above, the hydrogen radicals 204 generated by heating the metal wire 242 provided in the nozzle 24 promote removal of halogen elements sticking onto the surface of the substrate 100. Therefore, a release time of inert gas 203 can be more shortened than before. Accordingly, even with a single-wafer ALD apparatus which processes the substrates 100 one by one, a time for a film formation process can be shortened.

Moreover, also in the present embodiment, the nozzle 24 is provided in the chamber 20. The hydrogen radicals 204 generated in the nozzle 24 can be therefore immediately released toward the substrate 100, which enables halogen elements to be removed more quickly than before.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor manufacturing apparatus comprising:
a chamber to house at least one substrate;
a process gas nozzle to release process gas toward the substrate in the chamber;
an inert gas nozzle to release inert gas toward the substrate in the chamber;
a hydrogen radical nozzle disposed in the chamber and to generate hydrogen radicals by heating raw material gas including hydrogen and to release the generated hydrogen radicals toward the substrate during the release of the inert gas, wherein
a metal wire is in the hydrogen radical nozzle, and the metal wire includes a metal catalyst for exciting the generation of the hydrogen radicals.

2. The semiconductor manufacturing apparatus according to claim 1, wherein a variable power supply is connected to the metal wire.

3. The semiconductor manufacturing apparatus according to claim 1, further comprising
a support member to support the substrates with these substrates stacked on one another in the chamber, wherein
the hydrogen radical nozzle includes a plurality of release ports along a stack direction of the substrates.

4. The semiconductor manufacturing apparatus according to claim 1, further comprising
a support member to rotationally move the substrate in the chamber, wherein
the process gas nozzle, the inert gas nozzle and the hydrogen radical nozzle are disposed above the support member spaced from one another along a rotational direction.

5. The semiconductor manufacturing apparatus according to claim 4, wherein each of the process gas nozzle, the inert gas nozzle and the hydrogen radical nozzle includes a plurality of release ports along a radial direction.

6. The semiconductor manufacturing apparatus according to claim 1, wherein the metal catalyst is tungsten.

7. The semiconductor manufacturing apparatus according to claim 1, wherein a shape of the metal wire is helical.

8. The semiconductor manufacturing apparatus according to claim 1, wherein the process gas nozzle includes a first process gas nozzle to release precursor gas and a second process gas nozzle to release reactant gas.

9. The semiconductor manufacturing apparatus according to claim 4, wherein
the process gas nozzle includes a first process gas nozzle to release precursor gas and a second process gas nozzle to release reactant gas, and
the inert gas nozzles are respectively disposed between the first process gas nozzle and the second process gas nozzle, between the second process gas nozzle and the hydrogen radical nozzle, and between the hydrogen radical nozzle and the first process gas nozzle, and release the inert gas continuously.

10. A manufacturing method of a semiconductor device, comprising:
housing at least one substrate in a chamber;
releasing process gas toward the substrate in the chamber;
releasing inert gas toward the substrate in the chamber after the release of the process gas;
heating raw material gas including hydrogen by supplying a current to a metal wire in a hydrogen radical nozzle disposed in the chamber, generating hydrogen radicals by the heating of the raw material gas and by the use of a metal catalyst contained in the metal wire, and releasing the generated hydrogen radicals from the hydrogen radical nozzle toward the substrate during the release of the inert gas.
